(19) United States
(12) Patent Application Publication
(10) Pub. No.: US 2015/0270338 A1
(43) Pub. Date: Sep. 24, 2015

(54) TRANSISTOR CHIP AND SEMICONDUCTOR DEVICE

(71) Applicant: Mitsubishi Electric Corporation, Tokyo (JP)

(72) Inventor: Shin Chaki, Tokyo (JP)

(21) Appl. No.: 14/565,506

(22) Filed: Dec. 10, 2014

(30) Foreign Application Priority Data
Mar. 18, 2014 (JP) 2014-055335

(51) Int. Cl. H01L 29/06; H01L 27/088

(52) U.S. Cl. CPC H01L 29/0649; H01L 27/088

(57) ABSTRACT

A transistor chip includes at least two transistor cells; and a separation region electrically separating operation regions of the transistor cells from each other, wherein each of the transistor cells includes a gate pad, a drain pad, and a source pad.

### BACKGROUND OF THE INVENTION

1. Field of the Invention

The present invention relates to a transistor chip and a semiconductor device wherein a plurality of transistor cells are provided on one transistor chip.

2. Background Art

In a semiconductor device such as an internally matching amplifier, a total gate width, parallel combination number and the like of a semiconductor transistor to be used are determined for each circuit by considering an output, a gain, efficiency, a used frequency and the like. The total gate width of the transistor is determined by a gate width of a unit transistor determined by a unit gate width and the number of gate fingers per transistor (hereinafter referred to as a 1-cell transistor), the number of 1-cell transistors per chip (cell number), and the chip number. Therefore, wafer process masks of transistor chips are basically different in semiconductor devices with different outputs, used frequencies and the like, and the number of wafer process masks corresponding to the number of types of the semiconductor device is needed. In a prior-art transistor chip, a plurality of transistor cells is provided on one chip, and their operation regions are integrated or electrically connected by wiring or the like (see Japanese Patent Laid-Open No. 9-45706, for example).

### SUMMARY OF THE INVENTION

Each one of electrically connected transistor cells cannot be inspected individually and thus, inspection items in a wafer state are limited. If the number of cells to be integrated further increases, inspections that can be conducted are further limited. At least an inspection relating to RF characteristics in the wafer state is impossible, but if only a DC inspection is conducted, defective products can proceed to the subsequent processes. If there is abnormality in one transistor cell in a chip, the entirety including the other non-defective cells is determined to be NG, and many other portions with non-defective characteristics are disposed of as defectives.

In view of the above-described problems, an object of the present invention is to provide a transistor chip and a semiconductor device capable of improving productivity and reliability.

According to the present invention, a transistor chip includes: at least two transistor cells; and a separation region electrically separating operation regions of the transistor cells from each other, wherein each of the transistor cells includes a gate pad, a drain pad, and a source pad.

In the present invention, a plurality of transistor cells are provided on one transistor chip, and they are electrically separated from each other by the separation regions. Thus, the individual transistor cells can be independently inspected. As a result, productivity and reliability can be improved.

Other and further objects, features and advantages of the invention will appear more fully from the following description.

### BRIEF DESCRIPTION OF THE DRAWINGS

FIG. 1 is a plan view illustrating a semiconductor device according to Embodiment 1 of the present invention.

FIG. 2 is a plan view illustrating a transistor chip according to Embodiment 1 of the present invention.

FIGS. 3 and 4 are plan views illustrating a manufacturing method of the transistor chip according to Embodiment 1 of the present invention.

FIG. 5 is a plan view illustrating a variation of the transistor chip according to Embodiment 1 of the present invention.

FIG. 6 is a plan view illustrating a manufacturing method of a variation of the transistor chip according to Embodiment 1 of the present invention.

FIG. 7 is an enlarged plan view of a semiconductor device according to Embodiment 2 of the present invention.

FIG. 8 is an enlarged plan view illustrating a semiconductor device according to Embodiment 3 of the present invention.

FIG. 9 is a plan view illustrating a semiconductor device according to Embodiment 4 of the present invention.

### DETAILED DESCRIPTION OF THE PREFERRED EMBODIMENTS

A transistor chip and a semiconductor device according to the embodiments of the present invention will be described with reference to the drawings. The same components will be denoted by the same symbols, and the repeated description thereof may be omitted.

### Embodiment 1

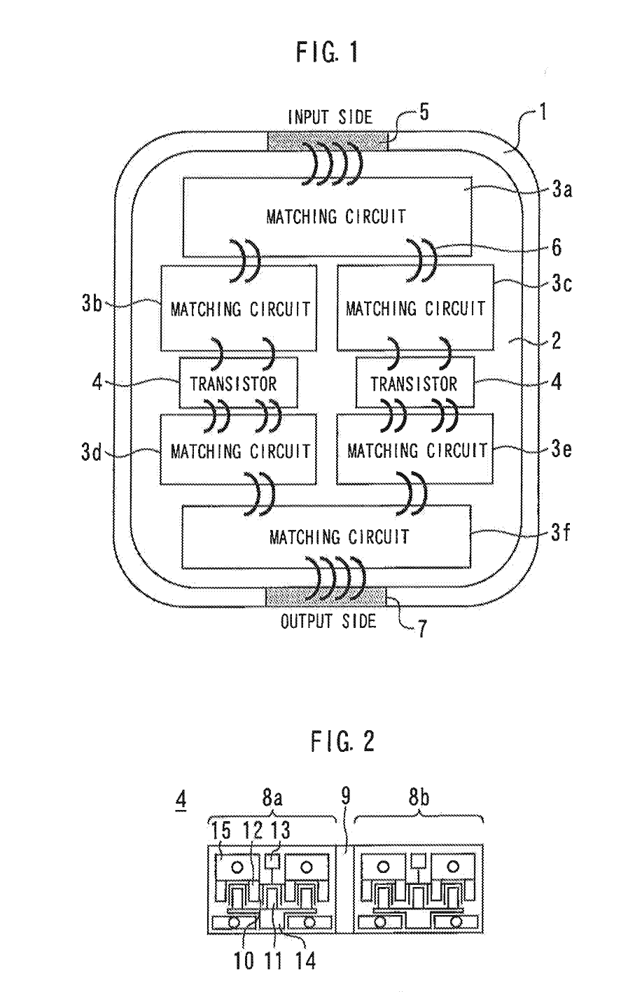

FIG. 1 is a plan view illustrating a semiconductor device according to Embodiment 1 of the present invention. In a mounted region 2 in a package 1, matching circuits 3a to 3f and a transistor chip 4 are provided. The matching circuits 3a to 3c are connected through wires 6 between an input electrode pad 5 and the transistor chip 4 on the package 1. Matching circuits 3d to 3f are connected between an output electrode pad 7 and the transistor chip 4 on the package 1. This semiconductor device is an internal matching amplifier in which the two transistor chips 4 are connected in parallel.

FIG. 2 is a plan view illustrating a transistor chip according to Embodiment 1 of the present invention. The transistor chip 4 has two transistor cells 8a and 8b and a separation region 9 for electrically separating operation regions of the transistor cells 8a and 8b from each other. Each of the transistor cells 8a and 8b has a gate electrode 10, a drain electrode 11, a source electrode 12, one gate pad 13, one drain pad 14, and two source pads 15.

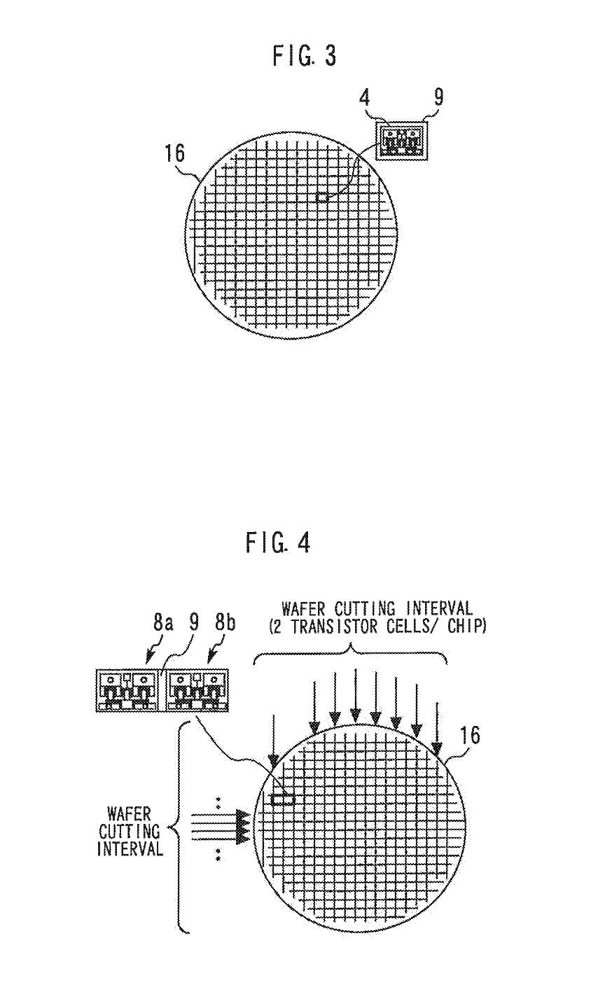

FIGS. 3 and 4 are plan views illustrating a manufacturing method of the transistor chip according to Embodiment 1 of the present invention. First, as illustrated in FIG. 3, a plurality of the transistor chips 4 corresponding to the transistor chips 4 are formed in a matrix state on a wafer 16. The individual transistor chips 4 are electrically separated from each other by the separation regions 9. Thus, the individual transistor cells can be inspected independently in a wafer state. Subsequently, as illustrated in FIG. 4, the wafer is cut along the separation regions 9 by considering the two transistor cells 8a and 8b as one chip.

As described above, in this embodiment, the two transistor cells 8a and 8b are provided on one transistor chip, and they are electrically separated from each other by the separation regions 9. Thus, the individual transistor cells 8a and 8b can be independently inspected. Therefore, the transistor cells 8a and 8b with defective characteristics can be removed in a range as small as possible, and non-defective transistor cells 8a and 8b can be used to the maximum in the subsequent processes. Since wafer process masks of the transistor cells 8a and 8b can be made common, the number of types of the wafer process masks can be reduced.

Moreover, since the gate widths of the individual transistor cells 8a and 8b become sufficiently smaller than the gate width in actual use, deterioration in yield in defective items in proportion to the gate width such as crystal defects can be reduced. Then, inspections, DC aging, RF aging and the like can be performed by easily inputting DC and RF signals through on-wafer probing. As a result, productivity and reliability can be improved.

Moreover, since the number of transistor cells included in 1 chip can be feely selected, the gate width according to the output and the frequency can be selected easily. Furthermore, arrangement of the transistor considering a heat generation state when being mounted can be made.

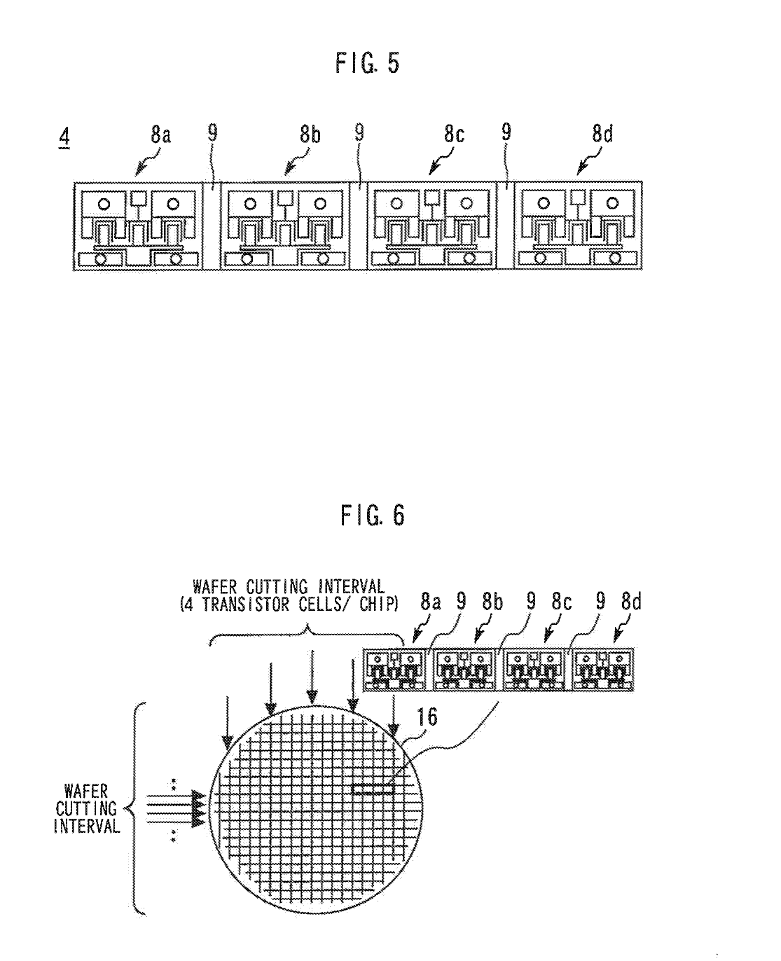

FIG. 5 is a plan view illustrating a variation of the transistor chip according to Embodiment 1 of the present invention. In the transistor chip 4, four transistor cells 8a to 8d are provided, and they are electrically separated from each other by the separation regions 9. FIG. 6 is a plan view illustrating a manufacturing method of a variation of the transistor chip according to Embodiment 1 of the present invention. As illustrated in FIG. 6, the wafer is cut along the separation regions 9 by considering the four transistor cells 8a to 8d as one chip. In this case, too, the above-described effect can be obtained. That is, by providing the two or more transistor cells on one transistor chip and by electrically separating them from each other by the separation regions 9, the above-described effect can be obtained.

### Embodiment 2

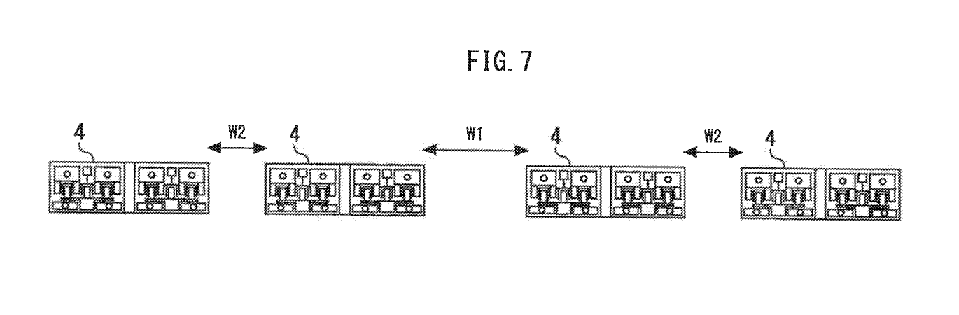

FIG. 7 is an enlarged plan view of a semiconductor device according to Embodiment 2 of the present invention. Heat generated from the plurality of transistor chips 4 might concentrate on a center part of the mounted region 2.

Particularly in an internal matching circuit with a large output exceeding 10 W or the like, the number of gate fingers and the number of cells of the transistor chip in use become large (the number of cells to be integrated can be 10 cells or more) and thus, heat concentration to the center part of the mounted region 2 is remarkable.

On the other hand, in this embodiment, in the plurality of transistor chips 4 juxtaposed on the mounted region 2, an interval W1 of the plurality of transistor chips 4 at the center part of the mounted region 2 is larger than an interval W2 of the plurality of transistor chips 4 in a peripheral part of the mounted region 2. As a result, heat concentration at the center part of the mounted region 2 can be prevented, and heat radiation can be improved.

### Embodiment 3

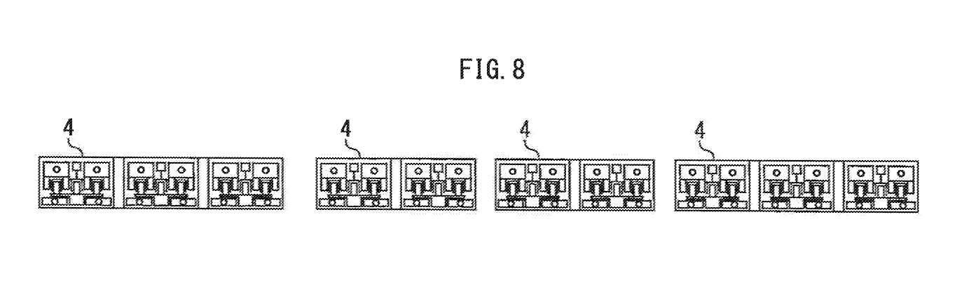

FIG. 8 is an enlarged plan view illustrating a semiconductor device according to Embodiment 3 of the present invention. In the plurality of transistor chips 4 juxtaposed on the mounted region 2, the number of transistor cells of the transistor chip 4 at the center part of the mounted region 2 is smaller than the number of transistor cells of the transistor chip 4 in the peripheral part of the mounted region 2. As a result, heat concentration at the center part of the mounted region 2 can be prevented, and heat radiation can be improved.

### Embodiment 4

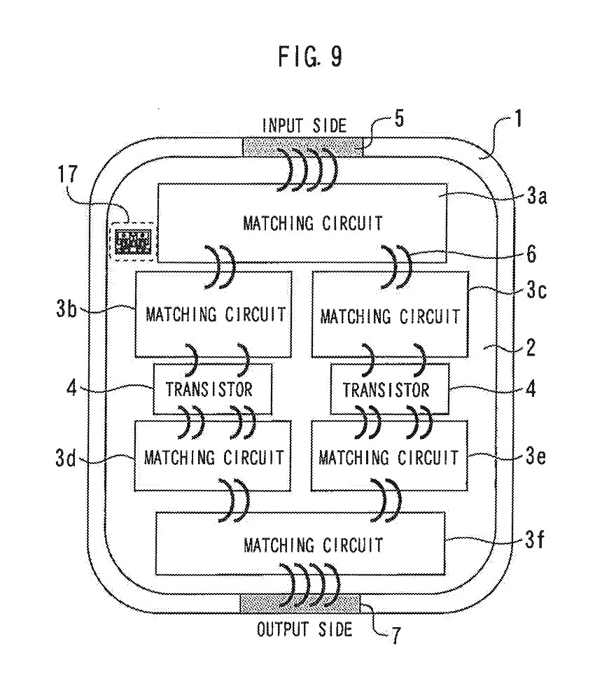

FIG. 9 is a plan view illustrating a semiconductor device according to Embodiment 4 of the present invention. If an internal matching amplifier with a large output fails, all the transistors might be burned out, and failure analysis becomes practically impossible. Thus, in this embodiment, a analytical transistor chip 17 not electrically connected to a circuit such as the transistor chip 4 and the like is provided on a blank part of the mounted region 2 in the package 1. Failure analysis is made possible by this analytical transistor chip In the above-described embodiments, the examples in which the present invention is applied to the internal matching circuit are explained. Not limited to them, the present invention can be applied to a discrete amplifier without the matching amplifier provided or a pre-match amplifier with the matching circuit provided but matching with a circuit outside the package, and the similar effect can be obtained.

Obviously many modifications and variations of the present invention are possible in the light of the above teachings. It is therefore to be understood that within the scope of the appended claims the invention may be practiced otherwise than as specifically described.

The entire disclosure of Japanese Patent Application No. 2014-055335, filed on Mar. 18, 2014, including specification, claims, drawings, and summary, on which the Convention priority of the present application is based, is incorporated herein by reference in its entirety.

1. A transistor chip comprising:
at least two transistor cells; and
a separation region electrically separating operation regions of the transistor cells from each other, wherein each of the transistor cells includes a gate pad, a drain pad, and a source pad.

2. A semiconductor device comprising:
a package; and
a plurality of transistor chips provided on a mounted region in the package, wherein
each of the transistor chips includes at least two transistor cells and a separation region electrically separating operation regions of the transistor cells from each other, and
an interval between the plurality of transistor chips at a center part of the mounted region is larger than an interval between the plurality of transistor chips in a peripheral part of the mounted region.

3. A semiconductor device comprising:
a package; and
a plurality of transistor chips provided on a mounted region in the package, wherein
each of the transistor chips includes at least two transistor cells and a separation region electrically separating operation regions of the transistor cells from each other, and
a number of the transistor cells of a first transistor chip at a center part of the mounted region is smaller than a number of the transistor cells of a second transistor chip in a peripheral part of the mounted region.

4. A semiconductor device comprising:
a package;
at least one transistor chip provided on a mounted region in the package; and
an analytical transistor chip provided on a blank part of the mounted region in the package and electrically isolated from the at least one transistor chip, wherein the at least one transistor chip includes at least two transistor cells and a separation region electrically separating operation regions of the transistor cells from each other.
